(19) United States
(12) Patent Application Publication
(10) Pub. No.: US 2025/0199052 A1
(43) Pub. Date: Jun. 19, 2025

(54) DEVICE AND METHOD FOR MONITORING AN INSULATION RESISTANCE OF A VEHICLE

(71) Applicants: HYUNDAI MOTOR COMPANY, Seoul (KR); KIA CORPORATION, Seoul (KR)

(72) Inventor: Jinyoung Hwang, Hwaseong-si (KR)

(73) Assignees: HYUNDAI MOTOR COMPANY, Seoul (KR); KIA CORPORATION, Seoul (KR)

(21) Appl. No.: 18/940,154

(22) Filed: Nov. 7, 2024

(30) Foreign Application Priority Data
Dec. 13, 2023 (KR) 10-2023-0180574

(51) Int. Cl. G01R 31/14; G01R 31/00

(52) U.S. Cl. CPC G01R 31/14; G01R 31/006

(57) ABSTRACT

Disclosed are a device and a method for monitoring an insulation resistance of a vehicle. The device is a device for monitoring an insulation resistance of a vehicle using a vehicle body as a ground point. The device includes: a monitoring resistance having a predetermined resistance value; a first switch connecting the monitoring resistance to the ground point or to a first node; a second switch connecting the monitoring resistance to the ground point or to a second node; a third switch connecting the first node to a positive electrode of an auxiliary battery pack or to a positive electrode of a main battery pack; and a fourth switch connecting the second node to a negative electrode of the auxiliary battery pack or to a negative electrode of the main battery pack.

### CROSS-REFERENCE TO RELATED APPLICATION

This application claims priority to and the benefit of Korean Patent Application No. 10-2023-0180574, filed in the Korean Intellectual Property Office on Dec. 13, 2023, the entire contents of which are incorporated herein by reference.

### BACKGROUND

### (a) Technical Field

The disclosure relates to a device and a method for monitoring an insulation resistance of a vehicle.

### (b) Description of the Related Art

In accordance with ever-increasing exhaust gas regulations and demands for eco-friendly vehicles, the share of electric vehicles continues to increase. In a hybrid electric vehicle (HEV) or an electric vehicle (EV), a high-voltage battery is used as a main power source, and thus, it is important to secure the stability of the high-voltage component. In order to prevent an electric shock in a vehicle, it is necessary to completely insulate a high voltage side and a chassis ground (GND) side of the vehicle from each other. This is because, if an electrical leakage occurs in the high-voltage battery, a leakage current may flow through the chassis, causing an electric shock to a driver.

It has recently been developed to add an auxiliary battery to a main battery to increase a cruising range. In other words, since two high-voltage batteries are installed, two independent circuits separated from each other by a battery relay are formed.

The statements in this Background section merely provide background information related to the present disclosure and may not constitute prior art.

### SUMMARY

The present disclosure provides a device and a method for monitoring an insulation resistance of a vehicle capable of efficiently checking the insulation resistance in the vehicle in a case where one high-voltage battery is mounted and in a case where two high-voltage batteries (e.g. a main battery and an auxiliary battery) are mounted.

An embodiment of the present disclosure provides a device for monitoring an insulation resistance of a vehicle using a vehicle body as a ground point. The device includes: a monitoring resistance having a predetermined resistance value; a first switch connecting the monitoring resistance to the ground point or to a first node; and a second switch connecting the monitoring resistance to the ground point or to a second node. The device further includes: a third switch connecting the first node to a positive electrode of an auxiliary battery pack or to a positive electrode of a main battery pack; and a fourth switch connecting the second node to a negative electrode of the auxiliary battery pack or to a negative electrode of the main battery pack.

In some embodiments, in an operation mode in which a first insulation resistance between the positive electrode of the main battery pack and the ground point is measured, the first switch may connect the monitoring resistance to the ground point, the second switch may connect the monitoring resistance to the second node, and the fourth switch may connect the second node to the negative electrode of the main battery pack.

In some embodiments, the first insulation resistance may be calculated according to Equation 1:

$${R}_{M\_ISOP} = {R}_{ST} \cdot ( 1 + \frac{{V}_{M} 2}{{V}_{M} 1} ) ( \frac{{V}_{M} 1 - {V}^{′}}{{V}^{′}} ) \qquad ( Equation 1 )$$

where R_{M_ISOP} represents the first insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

In some embodiments, in an operation mode in which a second insulation resistance between the negative electrode of the main battery pack and the ground point is measured, the first switch may connect the monitoring resistance to the first node, the second switch may connect the monitoring resistance to the ground point, and the third switch may connect the first node to the positive electrode of the main battery pack.

In some embodiments, the second insulation resistance may be calculated according to Equation 2:

$${R}_{M\_ISON} = {R}_{ST} \cdot ( 1 + \frac{{V}_{M} 1}{{V}_{M} 2} ) ( \frac{{V}_{M} 2 - {V}^{′}}{{V}^{′}} ) \qquad ( Equation 2 )$$

where R_{M_ISON} represents the second insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

In some embodiments, in an operation mode in which a third insulation resistance between the positive electrode of the auxiliary battery pack and the ground point is measured, the first switch may connect the monitoring resistance to the ground point, the second switch may connect the monitoring resistance to the second node, and the fourth switch may connect the second node to the negative electrode of the auxiliary battery pack.

In some embodiments, the third insulation resistance may be calculated according to Equation 3:

$${R}_{S\_ISOP} = {R}_{ST} \cdot ( 1 + \frac{{V}_{S} 2}{{V}_{S} 1} ) ( \frac{{V}_{S} 1 - {V}^{′}}{{V}^{′}} ) \qquad ( Equation 3 )$$

where R_{S_ISOP} represents the third insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

In some embodiments, in an operation mode in which a fourth insulation resistance between the negative electrode of the auxiliary battery pack and the ground point is measured, the first switch may connect the monitoring resistance to the first node, the second switch may connect the monitoring resistance to the ground point, and the third switch may connect the first node to the positive electrode of the auxiliary battery pack.

In some embodiments, the fourth insulation resistance may be calculated according to Equation 4:

$${R}_{S\_ISON} = {R}_{ST} \cdot ( 1 + \frac{{V}_{S} 1}{{V}_{S} 2} ) ( \frac{{V}_{S} 2 - {V}^{′}}{{V}^{′}} ) \qquad ( Equation 4 )$$

where R_{S_ISON} represents the fourth insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

In some embodiments, the device may sequentially and repeatedly performs, in a predetermined order: a first operation mode in which a first insulation resistance between the positive electrode of the main battery pack and the ground point is measured; a second operation mode in which a second insulation resistance between the negative electrode of the main battery pack and the ground point is measured; a third operation mode in which a third insulation resistance between the positive electrode of the auxiliary battery pack and the ground point is measured; and a fourth operation mode in which a fourth insulation resistance between the negative electrode of the auxiliary battery pack and the ground point is measured.

In some embodiments, when the positive electrode and the negative electrode of the main battery pack are connected to the positive electrode and the negative electrode of the auxiliary battery pack, respectively, by a battery relay, the device may alternately and repeatedly perform only: the first operation mode in which the first insulation resistance between the positive electrode of the main battery pack and the ground point is measured; and the second operation mode in which the second insulation resistance between the negative electrode of the main battery pack and the ground point is measured.

In some embodiments, when the positive electrode and the negative electrode of the main battery pack are connected to the positive electrode and the negative electrode of the auxiliary battery pack, respectively, by a battery relay, the device may alternately and repeatedly perform only: the third operation mode in which the third insulation resistance between the positive electrode of the auxiliary battery pack and the ground point is measured; and the fourth operation mode in which the fourth insulation resistance between the negative electrode of the auxiliary battery pack and the ground point is measured.

Another embodiment of the present disclosure provides a method for monitoring an insulation resistance of a vehicle using a vehicle body as a ground point, the method including: performing a first operation mode in which a first insulation resistance between a positive electrode of a main battery pack and the ground point is measured; performing a second operation mode in which a second insulation resistance between a negative electrode of the main battery pack and the ground point is measured; performing a third operation mode in which a third insulation resistance between a positive electrode of an auxiliary battery pack and the ground point is measured; and performing a fourth operation mode in which a fourth insulation resistance between a negative electrode of the auxiliary battery pack and the ground point is measured.

In some embodiments, the performing of the first operation mode may include: connecting a monitoring resistance having a predetermined resistance value to the ground point using a first switch; connecting the monitoring resistance to a second node using a second switch; connecting the second node to the negative electrode of the main battery pack using a fourth switch; and calculating the first insulation resistance according to Equation 1:

$${R}_{M\_ISOP} = {R}_{ST} \cdot ( 1 + \frac{{V}_{M} 2}{{V}_{M} 1} ) ( \frac{{V}_{M} 1 - {V}^{′}}{{V}^{′}} ) \qquad ( Equation 1 )$$

where R_{M_ISOP} represents the first insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V represents a voltage across the monitoring resistance.

In some embodiments, the performing of the second operation mode may include: connecting a monitoring resistance having a predetermined resistance value to a first node using a first switch; connecting the monitoring resistance to the ground point using a second switch; connecting the first node to the positive electrode of the main battery pack using a third switch; and calculating the second insulation resistance according to Equation 2:

$${R}_{M\_ISON} = {R}_{ST} \cdot ( 1 + \frac{{V}_{M} 1}{{V}_{M} 2} ) ( \frac{{V}_{M} 2 - {V}^{′}}{{V}^{′}} ) \qquad ( Equation 2 )$$

where R_{M_ISON} represents the second insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

In some embodiments, the performing of the third operation mode may include: connecting a monitoring resistance having a predetermined resistance value to the ground point using a first switch; connecting the monitoring resistance to a second node using a second switch; connecting the second node to the negative electrode of the auxiliary battery pack using a fourth switch; and calculating the third insulation resistance according to Equation 3:

$${R}_{S\_ISOP} = {R}_{ST} \cdot ( 1 + \frac{{V}_{S} 2}{{V}_{S} 1} ) ( \frac{{V}_{S} 1 - {V}^{′}}{{V}^{′}} ) \qquad ( Equation 3 )$$

where R_{S_ISOP} represents the third insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

In some embodiments, the performing of the fourth operation mode may include: connecting a monitoring resistance having a predetermined resistance value to a first node using a first switch; connecting the monitoring resistance to the ground point using a second switch; connecting the first node to the positive electrode of the auxiliary battery pack using a third switch; and calculating the fourth insulation resistance according to Equation 4:

$${R}_{S\_ISON} = {R}_{ST} \cdot ( 1 + \frac{{V}_{S} 1}{{V}_{S} 2} ) ( \frac{{V}_{S} 2 - {V}^{′}}{{V}^{′}} ) \qquad ( Equation 4 )$$

where R_{S_ISON} represents the fourth insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

In some embodiments, the method may further include: determining whether the positive electrode and the negative electrode of the main battery pack are connected to the positive electrode and the negative electrode of the auxiliary battery pack, respectively, by a battery relay; and when it is determined that the positive electrode and the negative electrode of the main battery pack are connected to the positive electrode and the negative electrode of the auxiliary battery pack, respectively, by the battery relay, sequentially and repeatedly performing, in a predetermined order, the first operation mode, the second operation mode, the third operation mode, and the fourth operation mode.

In some embodiments, the method may further include: when it is determined that the positive electrode and the negative electrode of the main battery pack are not connected to the positive electrode and the negative electrode of the auxiliary battery pack, respectively, by the battery relay, alternately and repeatedly performing only the first operation mode and the second operation mode.

In some embodiments, the method may further include: when it is determined that the positive electrode and the negative electrode of the main battery pack are not connected to the positive electrode and the negative electrode of the auxiliary battery pack, respectively, by the battery relay, alternately and repeatedly performing only the third operation mode and the fourth operation mode.

### BRIEF DESCRIPTION OF THE DRAWINGS

FIG. 1 is a block diagram illustrating a vehicle according to an embodiment of the present disclosure.

FIG. 2 is a circuit diagram illustrating a device for monitoring an insulation resistance according to an embodiment of the present disclosure.

FIGS. 3 to 7 are circuit diagrams each illustrating an operation of a device for monitoring an insulation resistance according to an embodiment of the present disclosure.

FIG. 8 is a flowchart illustrating a method for monitoring an insulation resistance according to an embodiment of the present disclosure.

The drawings described herein are for illustration purposes only and are not intended to limit the scope of the present disclosure in any way.

### DETAILED DESCRIPTION

Hereinafter, embodiments of the present disclosure are described in detail with reference to the accompanying drawings, so that they can be easily carried out by those of ordinary skill in the art to which the present disclosure pertains. However, the present disclosure may be implemented in various different forms, and is not limited to the embodiments described herein. In order to clearly explain the present disclosure, parts irrelevant to the description have been omitted from the drawings, and like elements are denoted by like reference numerals throughout the specification.

Throughout the specification and the claims, when a certain part is referred to as “including” a certain component, this implies the presence of other components, not precluding the presence of other components, unless explicitly stated to the contrary. Terms including ordinal numbers such as first and second may be used to describe various components, but these components are not limited by such terms. Such terms are used only for the purpose of distinguishing one component from another component.

When a component, device, element, apparatus, or the like of the present disclosure is described as having a purpose or performing an operation, function, or the like, the component, device, element, apparatus, or the like should be considered herein as being “configured to” meet that purpose or to perform that operation or function. Each component, controller, device, element, apparatus, and the like may separately embody or be included with a processor and a memory, such as a non-transitory computer readable media, as part of the device or apparatus.

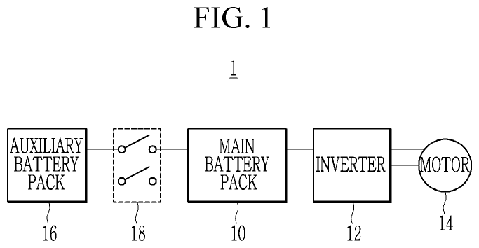

FIG. 1 is a block diagram illustrating a vehicle according to an embodiment.

Referring to FIG. 1, a vehicle 1 according to an embodiment may include a main battery pack 10, an inverter 12, a motor 14, an auxiliary battery pack 16, and a battery relay 18. The main battery pack 10 and the auxiliary battery pack 16 may supply power for driving the vehicle 1. The battery relay 18 may control a connection between the main battery pack 10 and the auxiliary battery pack 16. If the main battery pack 10 is discharged, the vehicle 1 may not start, and if another system that consumes a lot of current is connected to the main battery pack 10, the main battery pack 10 may be easily discharged. In a case where the auxiliary battery pack 16 is additionally used, the battery relay 18 disconnects the main battery pack 10 and the auxiliary battery pack 16 from each other, if necessary (for example, in a state where the vehicle 1 is turned off), thereby discharging only the auxiliary battery pack 16 and preventing the main battery pack 10 from being discharged.

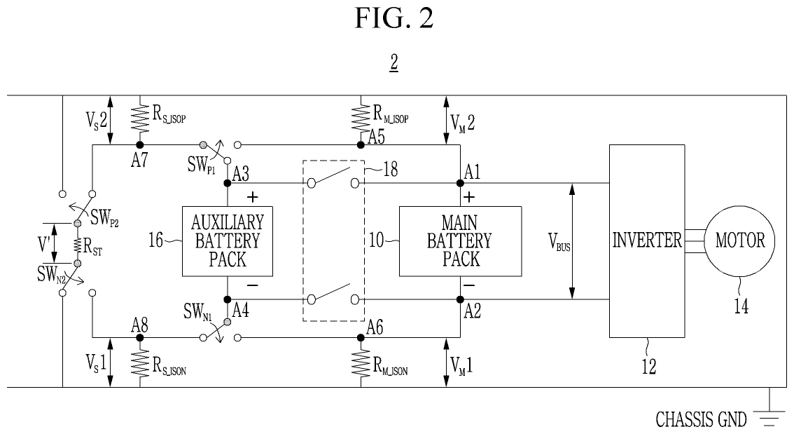

FIG. 2 is a circuit diagram illustrating a device for monitoring an insulation resistance according to an embodiment.

Referring to FIG. 2, a device 2 for monitoring an insulation resistance according to an embodiment is a device for monitoring an insulation resistance of a vehicle using a vehicle body as a ground point. The device includes a monitoring resistance R_{ST}, a first switch SW_{P2}, and a second switch SW_{N2}, a third switch SW_{P1}, and a fourth switch SW_{N1}. In the drawing, the ground point of the vehicle body is expressed as “chassis GND”.

The monitoring resistance R_{ST} may be provided to have a predetermined resistance value to calculate an insulation resistance. Therefore, the value of the monitoring resistance R_{ST} may be set to an appropriate value in consideration of various factors, such as data, detailed specifications, and driving environments of the vehicle actually applied.

The first switch SW_{P2} may connect the monitoring resistance R_{ST} to the ground point or to a node A7. The node A7 may represent any location on a positive electrode line of the auxiliary battery pack 16 where a voltage between the ground point of the vehicle and a positive electrode of the auxiliary battery pack 16 is measured. For example, a voltage between the ground point of the vehicle and the node A7 may be measured to measure a voltage across an insulation resistance R_{S_ISOP}.

The second switch SW_{N2} may connect the monitoring resistance R_{ST} to a ground point or to a node A8. The node A8 may represent any location on a negative electrode line of the auxiliary battery pack 16 where a voltage between the ground point of the vehicle and a negative electrode of the auxiliary battery pack 16 is measured. For example, a voltage between the ground point of the vehicle and the node A8 may be measured to measure a voltage across an insulation resistance R_{S_ISON}.

The third switch SW_{P1} may connect the node A7 to the positive electrode of the auxiliary battery pack 16, or connect the node A7 to a positive electrode of the main battery pack 10 through a node A5. The node A5 may represent any location on a positive electrode line of the main battery pack 10 where a voltage between the ground point of the vehicle and the positive electrode of the main battery pack 10 is measured. For example, a voltage between the ground point of the vehicle and the node A5 may be measured to measure a voltage across an insulation resistance R_{M_ISOP}.

The fourth switch SW_{N1} may connect the node A8 to the negative electrode of the auxiliary battery pack 16, or connect the node A8 to a negative electrode of the main battery pack 10 through a node A6. The node A6 may represent any location on a negative electrode line of the main battery pack 10 where a voltage between the ground point of the vehicle and the negative electrode of the main battery pack 10 is measured. For example, a voltage between the ground point of the vehicle and the node A6 may be measured to measure a voltage across an insulation resistance R_{M_ISON}.

In FIG. 2, VBUS may represent a voltage between the positive electrode line and the negative electrode line, V_{M}1 may represent a voltage between the negative electrode of the main battery pack 10 and the ground point, V_{M}2 may represent a voltage between the positive electrode of the main battery pack 10 and the ground point, V_{S}1 may represent a voltage between the negative electrode of the auxiliary battery pack 16 and the ground point, V_{S}2 may represent a voltage between the positive electrode of the auxiliary battery pack 16 and the ground point, and V′ may represent a voltage across the monitoring resistance R_{ST}.

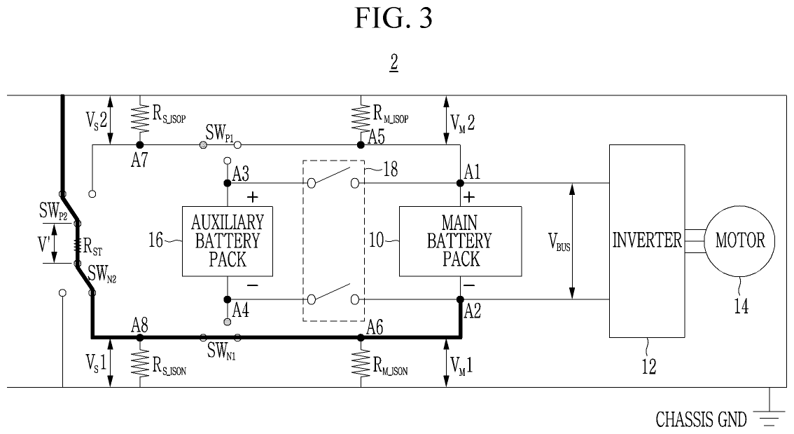

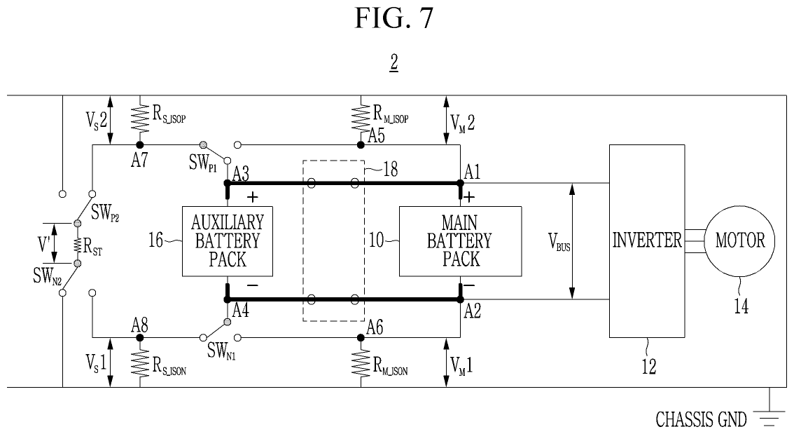

FIGS. 3 to 7 are circuit diagrams each illustrating an operation of a device for monitoring an insulation resistance according to an embodiment. In each of FIGS. 3 to 6, the positive electrode and negative electrode of the main battery pack 10 are not connected to the positive electrode and negative electrode of the auxiliary battery pack 16, respectively, by the battery relay 18. In FIG. 7, the positive electrode and the negative electrode of the main battery pack 10 are connected to the positive electrode and negative electrode of the auxiliary battery pack 16, respectively, by the battery relay 18.

Referring to FIG. 3, the device 2 for monitoring an insulation resistance according to an embodiment may operate in a first operation mode in which a first insulation resistance R_{M_ISOP} between the positive electrode of the main battery pack 10 and the ground point is measured.

In the first operation mode for measuring the first insulation resistance R_{M_ISOP}, the first switch SW_{P2} may connect the monitoring resistance R_{ST} to the ground point, the second switch SW_{N2} may connect the monitoring resistance R_{ST} to the node A8, and the fourth switch SW_{N1} may connect the node A8 to the negative electrode of the main battery pack 10. At the time of measuring the first insulation resistance R_{M_ISOP}, the position of the third switch SW_{P1} is irrelevant, and the third switch SW_{P1} may connect the node A7 to the positive electrode of the auxiliary battery pack 16 or to the positive electrode of the main battery pack 10. Accordingly, as emphasized by a thick line in FIG. 3, the negative electrode of the main battery pack 10, the monitoring resistance R_{ST}, and the ground point may be connected to one another in series.

The first insulation resistance R_{M_ISOP} may be calculated according to Equation 1.

$${R}_{M\_ISOP} = {R}_{ST} \cdot ( 1 + \frac{{V}_{M} 2}{{V}_{M} 1} ) ( \frac{{V}_{M} 1 - {V}^{′}}{{V}^{′}} ) \qquad [ Equation 1 ]$$

When an absolute value of the first insulation resistance R_{M_ISOP} (Ω/V) exceeds a predetermined value (for example, 500Ω/V based on North American SAE J1766), it may be determined that insulation is broken, and an alarm may be provided to a driver by displaying a warning light on a dashboard of the vehicle or the like.

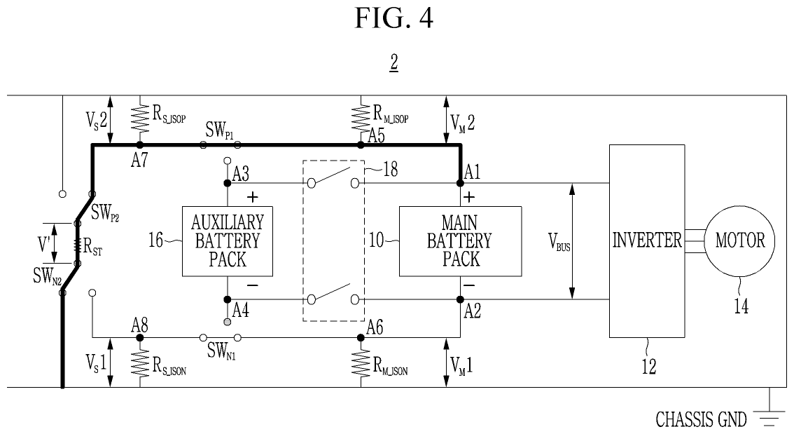

Referring to FIG. 4, the device 2 for monitoring an insulation resistance according to an embodiment may operate in a second operation mode in which a second insulation resistance R_{M_ISON} between the negative electrode of the main battery pack 10 and the ground point is measured.

In the second operation mode for measuring the second insulation resistance R_{M_ISON}, the first switch SW_{P2} may connect the monitoring resistance R_{ST} to the node A7, the second switch SW_{N2} may connect the monitoring resistance R_{ST} to the ground point, and the third switch SW_{P1} may connect the node A7 to the positive electrode of the main battery pack 10. At the time of measuring the second insulation resistance R_{M_ISON}, the position of the fourth switch SW_{N1} is irrelevant, and the fourth switch SW_{N1} may connect the node A8 to the negative electrode of the auxiliary battery pack 16 or to the negative electrode of the main battery pack 10. Accordingly, as emphasized by a thick line in FIG. 4, the negative electrode of the main battery pack 10, the monitoring resistance R_{ST}, and the ground point may be connected to one another in series.

The second insulation resistance R_{M_ISON} may be calculated according to Equation 2.

$${R}_{M\_ISON} = {R}_{ST} \cdot ( 1 + \frac{{V}_{M} 1}{{V}_{M} 2} ) ( \frac{{V}_{M} 2 - {V}^{′}}{{V}^{′}} ) \qquad [ Equation 2 ]$$

When an absolute value of the second insulation resistance R_{M_ISON} (Ω/V) exceeds a predetermined value (for example, 500Ω/V based on North American SAE J1766), it may be determined that insulation is broken, and an alarm may be provided to a driver by displaying a warning light on a dashboard of the vehicle or the like.

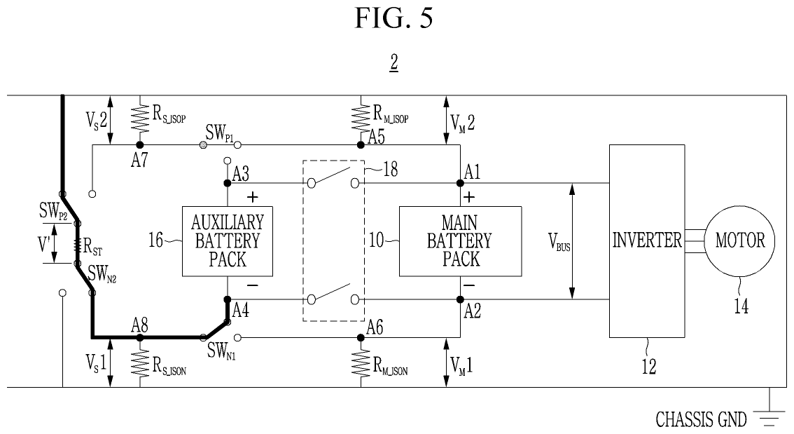

Referring to FIG. 5, the device 2 for monitoring an insulation resistance according to an embodiment may operate in a third operation mode in which a third insulation resistance R_{S_ISOP} between the positive electrode of the auxiliary battery pack 16 and the ground point is measured.

In the third operation mode for measuring the third insulation resistance R_{S_ISOP}, the first switch SW_{P2} may connect the monitoring resistance R_{ST} to the ground point, the second switch SW_{N2} may connect the monitoring resistance R_{ST} to the node A8, and the fourth switch SW_{N1} may connect the node A8 to the negative electrode of the auxiliary battery pack 16. At the time of measuring the third insulation resistance R_{S_ISOP}, the position of the third switch SW_{P1} is irrelevant, and the third switch SW_{P1} may connect the node A7 to the positive electrode of the auxiliary battery pack 16 or to the positive electrode of the main battery pack 10. Accordingly, as emphasized by a thick line in FIG. 5, the negative electrode of the auxiliary battery pack 16, the monitoring resistance R_{ST}, and the ground point may be connected to one another in series.

The third insulation resistance R_{S_ISOP} may be calculated according to Equation 3.

$${R}_{S\_ISOP} = {R}_{ST} \cdot ( 1 + \frac{{V}_{S} 2}{{V}_{S} 1} ) ( \frac{{V}_{S} 1 - {V}^{′}}{{V}^{′}} ) \qquad [ Equation 3 ]$$

When an absolute value of the third insulation resistance R_{S_ISOP} (Ω/V) exceeds a predetermined value (for example, 500Ω/V based on North American SAE J1766), it may be determined that insulation is broken, and an alarm may be provided to a driver by displaying a warning light on a dashboard of the vehicle or the like.

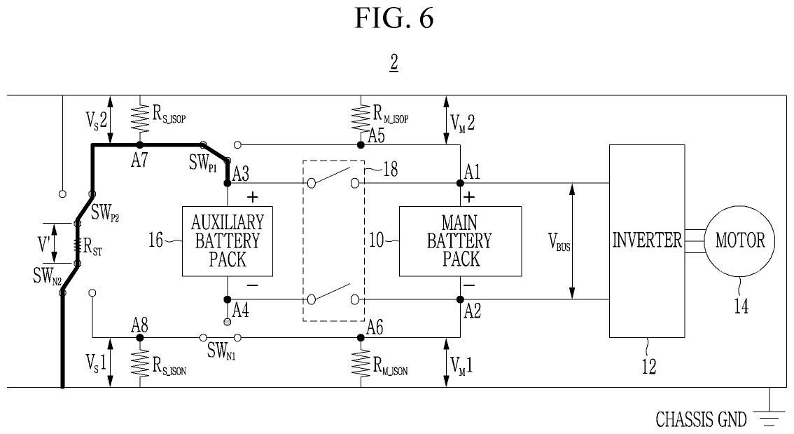

Referring to FIG. 6, the device 2 for monitoring an insulation resistance according to an embodiment may operate in a fourth operation mode in which a fourth insulation resistance R_{S_ISON} between the negative electrode of the auxiliary battery pack 16 and the ground point is measured.

In the fourth operation mode for measuring the fourth insulation resistance R_{S_ISON}, the first switch SW_{P2} may connect the monitoring resistance R_{ST} to the node A7, the second switch SW_{N2} may connect the monitoring resistance R_{ST} to the ground point, and the third switch SW_{P1} may connect the node A7 to the positive electrode of the auxiliary battery pack 16. At the time of measuring the fourth insulation resistance R_{S_ISON}, the position of the fourth switch SW_{N1} is irrelevant, and the fourth switch SW_{N1} may connect the node A8 to the negative electrode of the auxiliary battery pack 16 or to the negative electrode of the main battery pack 10. Accordingly, as emphasized by a thick line in FIG. 6, the positive electrode of the auxiliary battery pack 16, the monitoring resistance R_{ST}, and the ground point may be connected to one another in series.

The fourth insulation resistance R_{S_ISON} may be calculated according to Equation 4.

$${R}_{S\_ISON} = {R}_{ST} \cdot ( 1 + \frac{{V}_{S} 1}{{V}_{S} 2} ) ( \frac{{V}_{S} 2 - {V}^{′}}{{V}^{′}} ) \qquad [ Equation 4 ]$$

When an absolute value of the fourth insulation resistance R_{S_ISON} (Ω/V) exceeds a predetermined value (for example, 500Ω/V based on North American SAE J1766), it may be determined that insulation is broken, and an alarm may be provided to a driver by displaying a warning light on a dashboard of the vehicle or the like.

Continuous monitoring may be implemented as follows. The device 2 for monitoring an insulation resistance may perform continuous monitoring by sequentially and repeatedly performing the first operation mode in which the first insulation resistance R_{M_ISOP} between the positive electrode of the main battery pack 10 and the ground point is measured, the second operation mode in which the second insulation resistance R_{M_ISON} between the negative electrode of the main battery pack 10 and the ground point is measured, the third operation mode in which the third insulation resistance R_{S_ISOP} between the positive electrode of the auxiliary battery pack 16 and the ground point is measured, and the fourth operation mode in which the fourth insulation resistance R_{S_ISON} between the negative electrode of the auxiliary battery pack 16 and the ground point is measured in a predetermined order. Table 1 shows the states of the switches when continuous monitoring is performed.

TABLE 1

| Order | 1 | 2 | 3 | 4 |
|---|---|---|---|---|
| Insulation | R_{M}_{_{—}}_{ISOP} | R_{M}_{_{—}}_{ISON} | R_{S}_{_{—}}_{ISOP} | R_{S}_{_{—}}_{ISON} |
| resistance | | | | |
| Switch | Irrelevant | Connecting the node | Irrelevant | Connecting the node |
| SW_{P1} | | A7 to the positive | | A7 to the positive |
| | | electrode of the main | | electrode of the |
| | | battery pack 10 | | auxiliary battery pack |
| | | | | 16 |
| Switch | Connecting the node | Irrelevant | Connecting the node | Irrelevant |
| SW_{N1} | A8 to the negative | | A8 to the negative | |
| | electrode of the main | | electrode of the | |
| | battery pack 10 | | auxiliary battery pack | |
| | | | 16 | |
| Switch | Connecting the | Connecting the | Connecting the | Connecting the |
| SW_{P2} | monitoring resistance | monitoring resistance | monitoring resistance | monitoring resistance |
| | R_{ST} to the ground | R_{ST} to the node A7 | R_{ST} to the ground | R_{ST} to the node A7 |
| | point | | point | |
| Switch | Connecting the | Connecting the | Connecting the | Connecting the |
| SW_{N2} | monitoring resistance | monitoring resistance | monitoring resistance | monitoring resistance |
| | R_{ST} to the node A8 | R_{ST} to the ground | R_{ST} to the node A8 | R_{ST} to the ground |
| | | point | | point |

The order may be set differently depending on the actual implementation purpose or implementation environment.

Referring to FIG. 7, when the positive electrode and the negative electrode of the main battery pack 10 are connected to the positive electrode and the negative electrode of the auxiliary battery pack 16, respectively, by the battery relay 18, the device 2 for monitoring an insulation resistance according to an embodiment may alternately and repeatedly perform only the first operation mode in which the first insulation resistance R_{M_ISOP} between the positive electrode of the main battery pack 10 and the ground point is measured, and the second operation mode in which the second insulation resistance R_{M_ISON} between the negative electrode of the main battery pack 10 and the ground point is measured. Alternatively, the device 2 for monitoring an insulation resistance may alternately and repeatedly perform only the third operation mode in which the third insulation resistance R_{S_ISOP} between the positive electrode of the auxiliary battery pack 16 and the ground point is measured, and the fourth operation mode in which the fourth insulation resistance R_{S_ISON} between the negative electrode of the auxiliary battery pack 16 and the ground point is measured. When the battery relay 18 connects the main battery pack 10 and the auxiliary battery pack 16 to each other, the first insulation resistance R_{M_ISOP} is the same as the third the insulation resistance R_{S_ISOP}, and the second the insulation resistance R_{M_ISON} is the same as the fourth the insulation resistance R_{S_ISON}, and thus, there is no need to calculate all of the four insulation resistances. Table 2 and Table 3 show cases where continuous monitoring is performed.

TABLE 2

| Order | 1 | 2 | 3 | 4 |
|---|---|---|---|---|
| Insulation | R_{M}_{_{—}}_{ISOP} | R_{M}_{_{—}}_{ISON} | R_{M}_{_{—}}_{ISOP} | R_{M}_{_{—}}_{ISON} |
| resistance | | | | |
| Switch | Irrelevant | Connecting the node | Irrelevant | Connecting the node |
| SW_{P1} | | A7 to the positive | | A7 to the positive |
| | | electrode of the main | | electrode of the main |
| | | battery pack 10 | | battery pack 10 |
| Switch | Connecting the node | Irrelevant | Connecting the node | Irrelevant |
| SW_{N1} | A8 to the negative | | A8 to the negative | |
| | electrode of the main | | electrode of the main | |
| | battery pack 10 | | battery pack 10 | |
| Switch | Connecting the | Connecting the | Connecting the | Connecting the |
| SW_{P2} | monitoring resistance | monitoring resistance | monitoring resistance | monitoring resistance |
| | R_{ST} to the ground | R_{ST} to the node A7 | R_{ST} to the ground | R_{ST} to the node A7 |
| | point | | point | |
| Switch | Connecting the | Connecting the | Connecting the | Connecting the |
| SW_{N2} | monitoring resistance | monitoring resistance | monitoring resistance | monitoring resistance |
| | R_{ST} to the node A8 | R_{ST} to the ground | R_{ST} to the node A8 | R_{ST} to the ground |
| | | point | | point |

TABLE 3

| Order | 1 | 2 | 3 | 4 |
|---|---|---|---|---|
| Insulation | R_{S}_{_{—}}_{ISOP} | R_{S}_{_{—}}_{ISON} | R_{S}_{_{—}}_{ISOP} | R_{S}_{_{—}}_{ISON} |
| resistance | | | | |
| Switch | Irrelevant | Connecting the node | Irrelevant | Connecting the node |
| SW_{P1} | | A7 to the positive | | A7 to the positive |
| | | electrode of the | | electrode of the |
| | | auxiliary battery pack | | auxiliary battery pack |
| | | 16 | | 16 |
| Switch | Connecting the node | Irrelevant | Connecting the node | Irrelevant |
| SW_{N1} | A8 to the negative | | A8 to the negative | |
| | electrode of the | | electrode of the | |
| | auxiliary battery pack | | auxiliary battery pack | |
| | 16 | | 16 | |
| Switch | Connecting the | Connecting the | Connecting the | Connecting the |
| SW_{P2} | monitoring resistance | monitoring resistance | monitoring resistance | monitoring resistance |
| | R_{ST} to the ground | R_{ST} to the node A7 | R_{ST} to the ground | R_{ST} to the node A7 |
| | point | | point | |
| Switch | Connecting the | Connecting the | Connecting the | Connecting the |
| SW_{N2} | monitoring resistance | monitoring resistance | monitoring resistance | monitoring resistance |
| | R_{ST} to the node A8 | R_{ST} to the ground | R_{ST} to the node A8 | R_{ST} to the ground |
| | | point | | point |

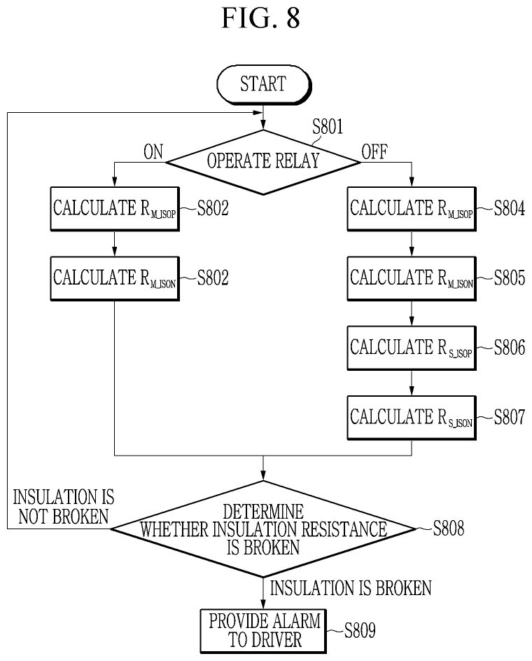

FIG. 8 is a flowchart illustrating a method for monitoring an insulation resistance according to an embodiment.

Referring to FIG. 8, the method for monitoring an insulation resistance according to an embodiment may include determining whether the battery relay 18 connects the positive electrode and the negative electrode of the main battery pack 10 to the positive electrode and the negative electrode of the auxiliary battery pack 16, respectively (in an operation S801). When the battery relay 18 is turned on and it is determined that the positive electrode and the negative electrode of the main battery pack 10 are connected to the positive electrode and the negative electrode of the auxiliary battery pack 16, respectively (“ON” in the operation S801), a first insulation resistance R_{M_ISOP} between the positive electrode of the main battery pack 10 and the ground point may be measured (in an operation S802) and a second insulation resistance R_{M_ISON} between the negative electrode of the main battery pack 10 and the ground point may be measured (in an operation S803)

Instead of steps 802 and 803, when the battery relay 18 is turned on and it is determined that the positive electrode and the negative electrode of the main battery pack 10 are connected to the positive electrode and the negative electrode of the auxiliary battery pack 16, respectively (“ON” in the operation S801), a third insulation resistance R_{S_ISOP} between the positive electrode of the auxiliary battery pack 16 and the ground point may be measured, and a fourth insulation resistance R_{S_ISON} between the negative electrode of the auxiliary battery pack 16 and the ground point may be measured.

On the other hand, when the battery relay 18 is turned off and it is determined that the positive electrode and the negative electrode of the main battery pack 10 are not connected to the positive electrode and the negative electrode of the auxiliary battery pack 16, respectively (“OFF” in the operation S801), a first insulation resistance R_{M_ISOP} between the positive electrode of the main battery pack 10 and the ground point may be measured (in an operation S804), a second insulation resistance R_{M_ISON} between the negative electrode of the main battery pack 10 and the ground point may be measured (in an operation S805), a third insulation resistance R_{S_ISOP} between the positive electrode of the auxiliary battery pack 16 and the ground point may be measured (in an operation S806), and a fourth insulation resistance R_{S_ISON} between the negative electrode of the auxiliary battery pack 16 and the ground point may be measured (in an operation S807).

Subsequently, as described above, it may be determined whether the insulation resistance is broken (in an operation S808), and when it is determined that insulation is broken, an alarm may be provided to a driver (in an operation S809). On the other hand, when it is determined that insulation is not broken, the process proceeds to step S801 and the steps of measuring the insulation resistances may be repeated.

According to embodiments, conventionally, two monitoring resistances have been used for one high-voltage battery to monitor an insulation resistance. Accordingly, in a case where two high-voltage batteries are installed, a total of four monitoring resistances have been needed to monitor an insulation resistance, and a separate circuit configuration has been required to measure the insulation resistance. In contrast, according to embodiments, only one monitoring resistance is required for monitoring insulation resistances of two high-voltage batteries, thereby reducing the vehicle manufacturing cost. In addition, since an insulation resistance is measured by controlling the monitoring resistance and the circuit configuration with logic, the circuit configuration is simplified, thereby implementing more stable continuous monitoring.

Although embodiments of the present disclosure have been described in detail above, the scope of the present disclosure is not limited thereto, and various modifications and improvements made by those having ordinary knowledge in the art to which the present disclosure pertains using the basic concept of the present disclosure defined in the following claims also fall within the scope of the present disclosure.

What is claimed is:

1. A device for monitoring an insulation resistance of a vehicle using a vehicle body as a ground point, the device comprising:
a monitoring resistance having a predetermined resistance value;
a first switch configured to connect the monitoring resistance to the ground point or to a first node;
a second switch configured to connect the monitoring resistance to the ground point or to a second node;
a third switch configured to connect the first node to a positive electrode of an auxiliary battery pack or to a positive electrode of a main battery pack; and
a fourth switch configured to connect the second node to a negative electrode of the auxiliary battery pack or to a negative electrode of the main battery pack.

2. The device of claim 1, wherein:
in an operation mode in which a first insulation resistance between the positive electrode of the main battery pack and the ground point is measured,
the first switch is configured to connect the monitoring resistance to the ground point,
the second switch is configured to connect the monitoring resistance to the second node, and
the fourth switch is configured to connect the second node to the negative electrode of the main battery pack.

3. The device of claim 2, wherein
the first insulation resistance is calculated according to Equation 1:
$${R}_{{M}_{ISOP}} = {R}_{ST} \cdot ( 1 + \frac{{V}_{M} 2}{{V}_{M} 1} ) ( \frac{{V}_{M} 1 - {V}^{′}}{{V}^{′}} ) \qquad ( Equation 1 )$$
where R_{M_ISOP} represents the first insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

4. The device of claim 1, wherein:
in an operation mode in which a second insulation resistance between the negative electrode of the main battery pack and the ground point is measured,
the first switch is configured to connect the monitoring resistance to the first node,
the second switch is configured to connect the monitoring resistance to the ground point, and
the third switch is configured to connect the first node to the positive electrode of the main battery pack.

5. The device of claim 4, wherein
the second insulation resistance is calculated according to Equation 2:
$${R}_{{M}_{ISON}} = {R}_{ST} \cdot ( 1 + \frac{{V}_{M} 1}{{V}_{M} 2} ) ( \frac{{V}_{M} 2 - {V}^{′}}{{V}^{′}} ) \qquad ( Equation 2 )$$
where R_{M_ISON} represents the second insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

6. The device of claim 1, wherein:
in an operation mode in which a third insulation resistance between the positive electrode of the auxiliary battery pack and the ground point is measured,
the first switch connects the monitoring resistance to the ground point,
the second switch connects the monitoring resistance to the second node, and
the fourth switch connects the second node to the negative electrode of the auxiliary battery pack.

7. The device of claim 6, wherein
the third insulation resistance is calculated according to Equation 3:
$${R}_{{S}_{ISOP}} = {R}_{ST} \cdot ( 1 + \frac{{V}_{S} 2}{{V}_{S} 1} ) ( \frac{{V}_{S} 1 - {V}^{′}}{{V}^{′}} ) \qquad ( Equation 3 )$$
where R_{S_ISOP} represents the third insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

8. The device of claim 1, wherein:
in an operation mode in which a fourth insulation resistance between the negative electrode of the auxiliary battery pack and the ground point is measured,
the first switch is configured to connect the monitoring resistance to the first node,
the second switch is configured to connect the monitoring resistance to the ground point, and
the third switch is configured to connect the first node to the positive electrode of the auxiliary battery pack.

9. The device of claim 8, wherein
the fourth insulation resistance is calculated according to Equation 4:
$${R}_{{S}_{ISON}} = {R}_{ST} \cdot ( 1 + \frac{{V}_{S} 1}{{V}_{S} 2} ) ( \frac{{V}_{S} 2 - {V}^{′}}{{V}^{′}} ) \qquad ( Equation 4 )$$
where R_{S_ISON} represents the fourth insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

10. The device of claim 1, wherein:
the device is configured to sequentially and repeatedly perform, in a predetermined order:
a first operation mode in which a first insulation resistance between the positive electrode of the main battery pack and the ground point is measured;
a second operation mode in which a second insulation resistance between the negative electrode of the main battery pack and the ground point is measured;
a third operation mode in which a third insulation resistance between the positive electrode of the auxiliary battery pack and the ground point is measured; and
a fourth operation mode in which a fourth insulation resistance between the negative electrode of the auxiliary battery pack and the ground point is measured.

11. The device of claim 1, wherein:
when the positive electrode and the negative electrode of the main battery pack are connected to the positive electrode and the negative electrode of the auxiliary battery pack, respectively, by a battery relay, the device is configured to alternately and repeatedly perform only:
a first operation mode in which a first insulation resistance between the positive electrode of the main battery pack and the ground point is measured; and
a second operation mode in which a second insulation resistance between the negative electrode of the main battery pack and the ground point is measured.

12. The device of claim 1, wherein:
when the positive electrode and the negative electrode of the main battery pack are connected to the positive electrode and the negative electrode of the auxiliary battery pack, respectively, by a battery relay, the device is configured to alternately and repeatedly performs only:
a third operation mode in which a third insulation resistance between the positive electrode of the auxiliary battery pack and the ground point is measured; and
a fourth operation mode in which a fourth insulation resistance between the negative electrode of the auxiliary battery pack and the ground point is measured.

13. A method for monitoring an insulation resistance of a vehicle using a vehicle body as a ground point, the method comprising:
performing a first operation mode in which a first insulation resistance between a positive electrode of a main battery pack and the ground point is measured;
performing a second operation mode in which a second insulation resistance between a negative electrode of the main battery pack and the ground point is measured;
performing a third operation mode in which a third insulation resistance between a positive electrode of an auxiliary battery pack and the ground point is measured; and
performing a fourth operation mode in which a fourth insulation resistance between a negative electrode of the auxiliary battery pack and the ground point is measured.

14. The method of claim 13, wherein
the performing of the first operation mode includes:
connecting a monitoring resistance having a predetermined resistance value to the ground point using a first switch;
connecting the monitoring resistance to a second node using a second switch;
connecting the second node to the negative electrode of the main battery pack using a fourth switch; and
calculating the first insulation resistance according to Equation 1:
$${R}_{{M}_{ISOP}} = {R}_{ST} \cdot ( 1 + \frac{{V}_{M} 2}{{V}_{M} 1} ) ( \frac{{V}_{M} 1 - {V}^{′}}{{V}^{′}} ) \qquad ( Equation 1 )$$
where R_{M_ISOP} represents the first insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

15. The method of claim 13, wherein
the performing of the second operation mode includes:
connecting a monitoring resistance having a predetermined resistance value to a first node using a first switch;
connecting the monitoring resistance to the ground point using a second switch;
connecting the first node to the positive electrode of the main battery pack using a third switch; and
calculating the second insulation resistance according to Equation 2:
$${R}_{{M}_{ISON}} = {R}_{ST} \cdot ( 1 + \frac{{V}_{M} 1}{{V}_{M} 2} ) ( \frac{{V}_{M} 2 - {V}^{′}}{{V}^{′}} ) \qquad ( Equation 2 )$$
where R_{M_ISON} represents the second insulation resistance, R_{ST} represents the monitoring resistance, V_{M}1 represents a voltage between the negative electrode of the main battery pack and the ground point, V_{M}2 represents a voltage between the positive electrode of the main battery pack and the ground point, and V′ represents a voltage across the monitoring resistance.

16. The method of claim 13, wherein
the performing of the third operation mode includes:
connecting a monitoring resistance having a predetermined resistance value to the ground point using a first switch;
connecting the monitoring resistance to a second node using a second switch;
connecting the second node to the negative electrode of the auxiliary battery pack using a fourth switch; and
calculating the third insulation resistance according to Equation 3:
$${R}_{{S}_{ISOP}} = {R}_{ST} \cdot ( 1 + \frac{{V}_{S} 2}{{V}_{S} 1} ) ( \frac{{V}_{S} 1 - {V}^{′}}{{V}^{′}} ) \qquad ( Equation 3 )$$
where R_{S_ISOP} represents the third insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

17. The method of claim 13, wherein
the performing of the fourth operation mode includes:
connecting a monitoring resistance having a predetermined resistance value to a first node using a first switch;
connecting the monitoring resistance to the ground point using a second switch;
connecting the first node to the positive electrode of the auxiliary battery pack using a third switch; and
calculating the fourth insulation resistance according to Equation 4:
$${R}_{{S}_{ISON}} = {R}_{ST} \cdot ( 1 + \frac{{V}_{S} 1}{{V}_{S} 2} ) ( \frac{{V}_{S} 2 - {V}^{′}}{{V}^{′}} ) \qquad ( Equation 4 )$$
where R_{S_ISON} represents the fourth insulation resistance, R_{ST} represents the monitoring resistance, V_{S}1 represents a voltage between the negative electrode of the auxiliary battery pack and the ground point, V_{S}2 represents a voltage between the positive electrode of the auxiliary battery pack and the ground point, and V′ represents a voltage across the monitoring resistance.

18. The method of claim 13, further comprising:
determining whether the positive electrode and the negative electrode of the main battery pack are connected to the positive electrode and the negative electrode of the auxiliary battery pack, respectively, by a battery relay; and
when it is determined that the positive electrode and the negative electrode of the main battery pack are connected to the positive electrode and the negative electrode of the auxiliary battery pack, respectively, by the battery relay, sequentially and repeatedly performing, in a predetermined order, the first operation mode, the second operation mode, the third operation mode, and the fourth operation mode.

19. The method of claim 18, further comprising:
when it is determined that the positive electrode and the negative electrode of the main battery pack are not connected to the positive electrode and the negative electrode of the auxiliary battery pack, respectively, by the battery relay, alternately and repeatedly performing only the first operation mode and the second operation mode.

20. The method of claim 18, further comprising:
when it is determined that the positive electrode and the negative electrode of the main battery pack are not connected to the positive electrode and the negative electrode of the auxiliary battery pack, respectively, by the battery relay, alternately and repeatedly performing only the third operation mode and the fourth operation mode.
